(19) United States
(12) Patent Application Publication
(10) Pub. No.: US 2024/0244924 A1
(43) Pub. Date: Jul. 18, 2024

(54) DISPLAY PANEL, MANUFACTURING METHOD THEREOF AND DISPLAY DEVICE

(71) Applicants: HEFEI XINSHENG OPTOELECTRONICS TECHNOLOGY CO., LTD., Hefei, Anhui (CN); BOE TECHNOLOGY GROUP CO., LTD., Beijing (CN)

(72) Inventors: Bin ZHOU, Beijing (CN); Ning LIU, Beijing (CN); Dacheng ZHANG, Beijing (CN); Liangchen YAN, Beijing (CN); Yu WANG, Beijing (CN)

(21) Appl. No.: 18/004,332

(22) PCT Filed: Jan. 29, 2022
(86) PCT No.: PCT/CN2022/074875

§ 371 Date: Jan. 5, 2023

(51) Int. Cl. H10K 59/80; H10K 59/122

(52) U.S. Cl. CPC H10K 59/80522; H10K 59/122

(57) ABSTRACT

An embodiment of the disclosure provides a display panel comprising a substrate, a display area of the display panel includes a plurality of sub-pixel regions, each sub-pixel includes a first pixel electrode and a second pixel electrode. The display panel further includes an auxiliary electrode connection region including an auxiliary electrode and an electrode connection structure on the substrate, the second pixel electrode is connected to the auxiliary electrode via the electrode connection structure, and an orthogonal projection of the auxiliary electrode connection region on the substrate has no overlap with orthogonal projections of the plurality of sub-pixel regions on the substrate. The electrode connection structure includes a first connection electrode on the auxiliary electrode, a second connection electrode on a side of the first connection electrode facing away the substrate, and a third connection electrode between the first connection electrode and the second connection electrode.

### TECHNICAL FIELD

The present disclosure relates to the field of display technologies, specifically to a display panel, a display device including the display panel, and a method for manufacturing the display panel.

### BACKGROUND

With the progress in technologies of semiconductor and material, electronic display products have been updated and developed rapidly. At present, the liquid crystal display has been widely used, new types of display devices such as an organic light emitting diode (OLED) display have also gained significant development. A transparent display device has present in some circumstances. For example, the transparent display device may be applied in display terminal in cars and subways, as well as show window in hotel, clothes shop and exhibition, to achieve authentic displaying effect.

Nevertheless, the display device is still desired to have a higher performance. For example, light transmittance of the display device is always expected to be as high as possible, and the image displayed by the display device is required to have a better uniformity in brightness.

### SUMMARY

An embodiment of the disclosure provides a display panel comprising a substrate, a display area of the display panel comprises a plurality of sub-pixel regions, each sub-pixel of the plurality of sub-pixel regions comprises a first pixel electrode on the substrate and a second pixel electrode on a side of the first pixel electrode facing away the substrate. The display panel further comprises an auxiliary electrode connection region, the auxiliary electrode connection region comprises an auxiliary electrode and an electrode connection structure on the substrate, the second pixel electrode is connected to the auxiliary electrode via the electrode connection structure, and an orthogonal projection of the auxiliary electrode connection region on the substrate has no overlap with orthogonal projections of the plurality of sub-pixel regions on the substrate. The electrode connection structure comprises a first connection electrode on the auxiliary electrode, a second connection electrode on a side of the first connection electrode facing away the substrate, and a third connection electrode between the first connection electrode and the second connection electrode. The third connection electrode comprises an upper surface contacting the second connection electrode, a lower surface contacting the first connection electrode and opposite to the upper surface, and a vertical section perpendicular to the upper surface or the lower surface, the vertical section comprises a top edge in the upper surface and a bottom edge in the lower surface, an orthogonal projection of the bottom edge on the substrate covers an orthogonal projection of the top edge on the substrate.

According to some embodiments of the disclosure, an orthogonal projection of the first connection electrode on the substrate covers an orthogonal projection of the second connection electrode on the substrate, an orthogonal projection of the third connection electrode on the substrate does not exceed the orthogonal projection of the second connection electrode on the substrate.

According to some embodiments of the disclosure, the vertical section comprises a side edge connecting the top edge to the bottom edge, the side edge intersects the lower surface at an intersecting point in the lower surface, a connection line from any point on the side edge to the intersecting point forms an angle with the lower surface, an opening of the angle faces the third connection electrode and is smaller than or equal to 90 degree.

According to some embodiments of the disclosure, the angle is greater than or equal to 45 degree and smaller than or equal to 70 degree.

According to some embodiments of the disclosure, the display panel further comprises a pixel definition layer on the substrate, the display area is divided into the plurality of sub-pixel regions by the pixel definition layer, the second pixel electrode extends beyond the pixel definition layer to contact at least one of the first connection electrode and the third connection electrode, the first pixel electrode and the electrode connection structure are isolated from each other by the pixel definition layer.

According to some embodiments of the disclosure, an orthogonal projection of the second connection electrode on the substrate covers an orthogonal projection of the third connection electrode on the substrate, such that the first connection electrode, the second connection electrode and the third connection electrode form a cavity having an opening, the opening faces the pixel definition layer, the second pixel electrode extends into the cavity through the opening and contacts the first connection electrode and the third connection electrode.

According to some embodiments of the disclosure, the cavity comprises an upper wall, a lower wall and a side wall, wherein a portion of the second connection electrode extending towards the pixel definition layer and exceeding the third connection layer serves as the upper wall, a portion of the first connection electrode extending towards the pixel definition layer and exceeding the third connection layer serves as the lower surface, the third connection electrode forms the side wall, and a length of the upper wall along a horizontal direction parallel to a surface of the substrate is smaller than a length of the lower surface along the horizontal direction.

According to some embodiments of the disclosure, the length of the lower wall along the horizontal direction is 4 to 10 times of the length of the upper wall along the horizontal direction.

According to some embodiments of the disclosure, a height of the third connection electrode in a second direction is 1.5 to 6 times of a height of the second pixel electrode in the second direction, the second direction is a vertical direction perpendicular to the horizontal direction.

According to some embodiments of the disclosure, the third connection electrode and the first pixel electrode are at a same layer and comprise a same material.

According to some embodiments of the disclosure, each of the third connection electrode and the first pixel electrode comprises a light reflective material.

According to some embodiments of the disclosure, the light reflective material comprises aluminum alloy.

According to some embodiments of the disclosure, the sub-pixel region further comprises a first conductive sub-layer and a second conductive sub-layer, the second conductive sub-layer is between the first pixel electrode and the second pixel electrode, the first conductive sub-layer is on a side of the first pixel electrode facing the substrate, the first conductive sub-layer and the first connection electrode are at a same layer and comprise a same material, the second conductive sub-layer and the second connection electrode are at a same layer and comprise a same material, the first conductive sub-layer and the second conductive sub-layer are isolated from the electrode connection structure by the pixel definition layer.

According to some embodiments of the disclosure, the display panel further comprises a pixel driving circuit configured to drive the plurality of sub-pixel regions to emit light, the pixel driving circuit comprises a transistor, the auxiliary electrode and a drain or a source of the transistor are at a same layer and comprise a same material.

According to some embodiments of the disclosure, respective second pixel electrodes in the plurality of sub-pixel regions are connected with each other to form an integral structure.

According to some embodiments of the disclosure, the display panel further a light shielding layer between the substrate and the pixel driving circuit, an orthogonal projection of the light shielding layer on the substrate covers an orthogonal projection of an active layer of the transistor on the substrate.

According to some embodiments of the disclosure, the display panel comprises a plurality of auxiliary electrode connection regions including the auxiliary electrode region, at least some of the plurality of auxiliary electrode regions are located between adjacent sub-pixel regions of the plurality of sub-pixel regions.

According to some embodiments of the disclosure, the display area comprises a plurality of display units, each display unit comprises at least three sub-pixel regions of the plurality of the sub-pixel regions, the display panel comprises a plurality of auxiliary electrode connection regions comprising the auxiliary electrode connection region, at least some of the plurality of auxiliary electrode connection regions are located between adjacent pixel units of the plurality of pixel units.

According to some embodiments of the disclosure, the display panel comprises a non-display area outside the display area, the display panel comprises a plurality of auxiliary electrode connection regions including the auxiliary electrode connection region, at least some of the plurality of auxiliary electrode connection regions are in the non-display area.

Another embodiment of the disclosure provides a display device, comprising the display panel according to any one of above embodiments.

Another embodiment of the disclosure provides a method for manufacturing a display panel, comprising: providing a substrate comprising a display area, the display area comprising a plurality of sub-pixel regions; fabricating, on the substrate, a first pixel electrode and a second pixel electrode for each of the plurality of sub-pixel regions, the second pixel electrode being on a side of the first pixel electrode facing away the substrate; fabricating, on the substrate, an auxiliary electrode and an electrode connection structure, such that the auxiliary electrode is connected to the second pixel electrode through the electrode connection structure, the electrode connection structure is located in the auxiliary electrode connection region, an orthogonal projection of the auxiliary electrode connection region on the substrate has no overlap with orthogonal projections of the plurality of sub-pixel regions on the substrate, the electrode connection structure comprises a first connection electrode on the auxiliary electrode, a second connection electrode on the first connection electrode facing away the substrate, and a third connection electrode between the first connection electrode and the second connection electrode, the third connection electrode comprises an upper surface contacting the second connection electrode, a lower surface contacting the first connection electrode and opposite to the upper surface, and a vertical section perpendicular to the upper surface or the lower surface, the vertical section comprises a top edge in the upper surface and a bottom edge in the lower surface, an orthogonal projection of the bottom edge on the substrate covers an orthogonal projection of the top edge on the substrate.

According to some embodiments of the disclosure, the method further comprises: fabricating a pixel driving circuit on the substrate, the pixel driving circuit comprising a transistor, fabricating the transistor and the auxiliary electrode comprises: forming a source-drain metal layer on the substrate, the source-drain metal layer extending to the auxiliary electrode connection region; and patterning the source-drain metal layer by means of a single patterning process to form a drain, a source of the transistor and the auxiliary electrode.

According to some embodiments of the disclosure, the sub-pixel region further comprises a first conductive sub-layer and a second conductive sub-layer, the second conductive sub-layer is between the first pixel electrode and the second pixel electrode, the first conductive sub-layer is on a side of the first pixel electrode facing the substrate, fabricating the electrode connection structure, the first conductive sub-layer, the second conductive sub-layer and the first pixel electrode comprises: fabricating a first conductive layer on the source, the drain and the auxiliary electrode; patterning the first conductive layer by a single pattern process to obtain the first conductive sub-layer and the first connection electrode, the first conductive sub-layer and the first connection electrode being connected to the drain of the transistor and the auxiliary electrode, respectively; forming a first pixel electrode layer and a second conductive layer on the first conductive sub-layer and the first connection electrode in sequence; etching the second conductive layer to form the second conductive sub-layer and the second connection electrode; and over etching the first pixel electrode layer at a position where the second conductive layer is etched, so as to form the first pixel electrode and the third connection electrode, an orthogonal projection of the second connection electrode on the substrate covering an orthogonal projection of the third connection electrode on the substrate.

According to some embodiments of the disclosure, the method further comprises: forming a pixel definition layer on the substrate, the display area being divided into a plurality of sub-pixel regions by the pixel definition layer, the first conductive sub-layer, the first pixel electrode and the second conductive sub-layer in the sub-pixel region are isolated from the electrode connection structure in the auxiliary electrode connection region by the pixel definition layer; and fabricating a light emission layer on the second conductive sub-layer, fabricating the second pixel electrode comprises: forming the second pixel electrode on the light emission layer and the pixel definition layer, the second pixel electrode extending beyond the pixel definition layer to contact at least one of the first connection electrode and the third connection electrode.

Some embodiments of the disclosure have been summarized. The embodiments will be further set forth in the following description. Additional embodiments different from the above embodiments can be obtained by combining the features in the above embodiments or combining different embodiments. These additional embodiments also pertain to the technical solution of the disclosure.

### BRIEF DESCRIPTION OF DRAWINGS

More details, features and advantages of the solution of the disclosure will be described in the following description to the illustrative embodiments with reference to the drawings, in which

FIG. 1 is a partial illustrative top view of a display panel according to an embodiment of the disclosure;

FIG. 2 illustrates a partial vertical section of the display panel taken along the line “B1-B2” shown in FIG. 1;

FIG. 3a illustrates a partial vertical section of an electrode connection structure in an auxiliary electrode connection region of a display panel according to another embodiment of the disclosure;

FIG. 3b illustrates a partial vertical section of an electrode connection structure in an auxiliary electrode connection region of a display panel according to yet another embodiment of the disclosure;

FIG. 4 illustrates a partial vertical section of a display panel according to another embodiment of the disclosure;

FIGS. 5 to 7 illustrates partial top views of display panels according to other embodiments of the disclosure, respectively;

FIG. 8 shows an overall flowchart of a method for manufacturing a display panel according to an embodiment of the disclosure;

FIG. 9 shows an overall flowchart of a method for manufacturing a display panel according to another embodiment of the disclosure;

FIG. 10 shows steps involved in manufacturing an electrode connection structure of a display panel according another embodiment of the disclosure;

FIGS. 11 to 16 illustrate partial vertical sections of a display panel during different steps in the process of manufacturing the display panel according to another embodiment of the disclosure.

### DETAILED DESCRIPTION OF EMBODIMENTS

Next, several embodiments of the application will be described in detail by referring to the drawings, so that a person having an ordinary skill in the art is able to implement the technical solutions of the application. The technical solutions may be embodied in various forms, and are not limited to the embodiments set forth herein. These embodiments are provided to make the technical solutions clear and complete, but they are not intended to define the scope of the application.

Unless otherwise defined, the terms (including scientific terms and technical terms) used herein have the same meanings with as those commonly understood by the person having an ordinary skill in the art. It is to be understood that, the terms defined in typical dictionaries should be interpreted as having meanings consistent with those commonly explained in the related art and/or the context of this application, and they would not be explained in an ideal way or in a too formal sense, unless explicitly indicated.

In order to enhance a light transmittance of a display device, a pixel electrode of the display device may be manufactured thin, but this will result in an increased voltage drop in the extension path of pixel electrode. To reduce the voltage drop in the extension path of pixel electrode, it is proposed to fabricate an auxiliary electrode in the display device. However, there is still room for improvement for the solution of reducing the voltage drop in the pixel electrode by means of the auxiliary electrode. For example, the voltage drop in the extension path of pixel electrode cannot satisfy an excellent display performance of the display device, and fabricating the auxiliary electrode is quite complex.

An embodiment of the disclosure provides a display panel including a substrate. A display area of the display panel comprises a plurality of sub-pixel regions, each sub-pixel region comprises a first pixel electrode on the substrate and a second pixel electrode on the first pixel electrode facing away the substrate. The display panel further comprises an auxiliary electrode connection region, the auxiliary electrode connection region comprises an auxiliary electrode and an electrode connection structure on the substrate, the second pixel electrode is connected to the auxiliary electrode via the electrode connection structure. An orthogonal projection of the auxiliary electrode connection region on the substrate has no overlap with orthogonal projections of the plurality of sub-pixel regions on the substrate. The electrode connection structure comprises a first connection electrode on the auxiliary electrode, a second connection electrode on a side of the first connection electrode facing away the substrate, and a third connection electrode between the first connection electrode and the second connection electrode. The third connection electrode comprises an upper surface contacting the first connection electrode, a lower surface contacting the second connection electrode and opposite to the upper surface, and a vertical section perpendicular to the upper surface or the lower surface. The vertical section comprises a top edge in the upper surface and a bottom edge in the lower surface. An orthogonal projection of the bottom edge on the substrate covers an orthogonal projection of the top edge on the substrate.

The word “cover” and its conjugations herein are used to mean exceed or extend beyond. Accordingly, “an object A covers an object B” means that an area of the object A is greater than an area of the object B and a boundary of the object B is completely within the boundary of the object A. The first pixel electrode and the second pixel electrode herein refer to electrode structures for receiving an electrical signal to control the sub-pixel region emit light. For an organic light emitting diode (OLED) display panel, the first pixel electrode may be one of an anode and a cathode of an OLED, the second pixel electrode may be the other of the anode and the cathode of the OLED. An embodiment of the display panel of the disclosure will be illustrated by taking the case where the first pixel electrode is the anode of the OLED and the second pixel electrode is the cathode of the OLED as an example.

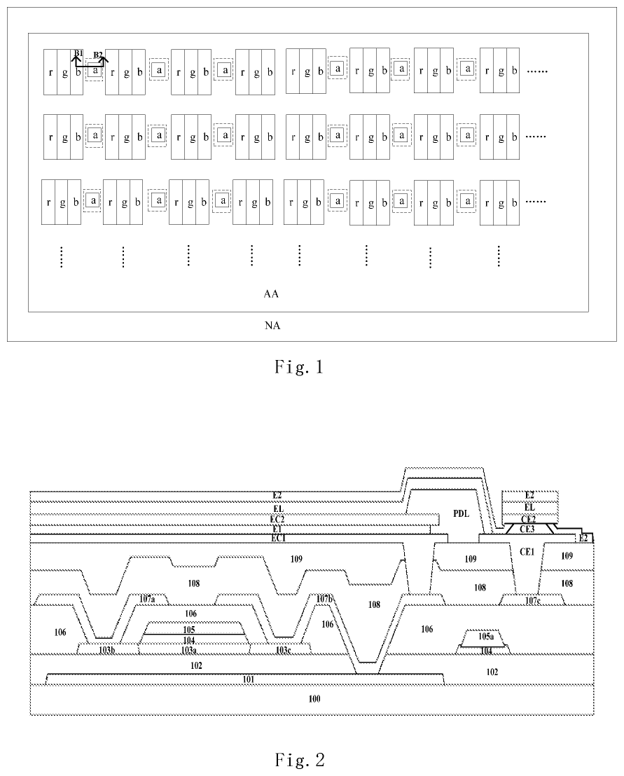

FIG. 1 illustrates a partial top view of a display panel according to an embodiment of the disclosure. As shown in FIG. 1, a display area AA of the display panel includes a plurality of sub-pixel regions such as a red sub-pixel region r, a green sub-pixel region g and a blue sub-pixel region b. The display area AA further comprises an auxiliary electrode connection region a that may be distributed between adjacent sub-pixel regions. In the example of FIG. 1, a single red sub-pixel region r, a single green sub-pixel region g and a single blue sub-pixel region b may combine into a pixel unit, the auxiliary electrode connection region a is located between adjacent pixel units. The sub-pixel regions of the display panel are not limited to the example shown in FIG. 1, in other embodiments, the display area may further comprise a white sub-pixel region, a yellow sub-pixel region, etc. The number of sub-pixel regions and arrangement of the sub-pixel areas in the display area AA are not essential to the technical solution of the disclosure, which will not be specifically limited herein.

As discussed above, the auxiliary electrode connection region comprises an auxiliary electrode and an electrode connection structure on the substrate, but this does not mean that the region where the auxiliary electrode extends on the substrate is restricted to the auxiliary electrode connection region. The auxiliary electrode may be distributed in the display area and non-display area of the display panel, as long as the normal light emission of the sub-pixel regions in the display area is not affected. In some embodiment, the auxiliary electrode may be distributed along a gap between pixel units or a gap between sub-pixel regions. For example, in FIG. 1, the region of the auxiliary electrode is schematically shown as dashed rectangle line box, it can be seen that the region of the auxiliary electrode is greater than the auxiliary electrode connection region. In other embodiments, the auxiliary electrode may extend into much more regions, e.g., the auxiliary electrode may be distributed in the gap between adjacent columns of pixel units and the gap between adjacent rows of pixel units. In some embodiments, all auxiliary electrodes distributed in different regions are connected to each other to from a patterned integral structure. FIG. 2 illustrates a partial vertical section of the display panel taken along a horizontal line between arrows B1-B2 shown in FIG. 1. The display panel comprises a substrate 100, a first pixel electrode E1, a second pixel electrode E2 and an auxiliary electrode 107c, the electrode connection structure connecting the auxiliary electrode 107c with the second pixel electrode E2 includes a first connection electrode CE1, a second connection electrode CE2 and a third connection electrode CE3 between the first connection electrode CE1 and the second connection electrode CE2. As shown in FIG. 2, the third connection electrode CE3 includes an upper surface contacting the second connection electrode CE2, a lower surface contacting the first connection electrode CE1 and opposite to the upper surface, and a vertical section perpendicular to the upper surface or the lower surface. The vertical section includes a top edge in the upper surface and a bottom edge in the lower surface, an orthogonal projection of the bottom edge on the substrate 100 covers an orthogonal projection of the top edge on the substrate 100. The specific positions of the top edge and bottom edge of the vertical section in the upper surface and the lower surface are not limited, that is, the vertical section shown in FIG. 2 only illustrates an example of a certain vertical section of the third connection electrode, in other words, it is not required that all vertical sections of the third connection electrode have the characteristic of the top edge and bottom edge as described above.

The existence of the auxiliary electrode 107c may reduce the voltage drop on the extension path of the second pixel electrode when the display panel is in operation. In this case, the second pixel electrode can be manufactured relatively thinner, which is advantageous to enhancing light transmittance of the display panel. Further, the orthogonal projection of the bottom edge of the vertical section of the third connection electrode on the substrate exceeds to cover the orthogonal projection of the top edge of the vertical section on the substrate, this means that the third connection electrode comprises a slope structure between the upper surface and the lower surface. As will be further discussed below, the slope structure is advantageous to achieve a greater contacting area between the second pixel electrode and the electrode connection structure, reducing a contact resistance between the second pixel electrode and the electrode connection structure, further effectively reducing the voltage drop on the extension path of the second pixel electrode when the display panel is in operation. Therefore, with this embodiment, light transmittance of the display panel can be enhanced by thinning the second pixel electrode while avoiding a large voltage drop on the second pixel electrode, thereby further improving brightness uniformity of the image displayed by the display panel.

As previously stated, the orthogonal projection of the auxiliary electrode connection region on the substrate has no overlap with the orthogonal projections of the plurality of sub-pixel regions on the substrate, thereby mitigating the influence to the normal light emission of the sub-pixel regions by the auxiliary electrode connection region as much as possible. The spatial relationship between the electrode connection structure and the auxiliary electrode in the auxiliary electrode connection region is not limited herein, the orthogonal projection of the electrode connection structure on the substrate may partially overlap the orthogonal projection of auxiliary electrode on the substrate or they do not overlap at all. As shown in FIG. 2, according to an embodiment of the disclosure, the electrode connection structure is at side of the auxiliary electrode 107c facing away the substrate 100 and right above the auxiliary electrode 107c, so as to reduce the area of the auxiliary electrode connection region. Moreover, the auxiliary electrode 107c is below an light emission layer of the sub-pixel region, to prevent the light emission layer to be affected by the auxiliary electrode 107c.

In some embodiments, an orthogonal projection of the first connection electrode on the substrate covers an orthogonal projection of the second connection electrode on the substrate, an orthogonal projection of the third connection electrode on the substrate does not exceed the orthogonal projection of the second connection electrode on the substrate. In this way, the electrode connection structure including the first connection electrode, the second connection structure and the third connection structure is able to have a vertical section like a Chinese character “ [symbol] ”, which is advantageous to a stable and effective connection of the second pixel electrode and the electrode connection structure during a process of manufacturing the display panel. For example, in the vertical section shown in FIG. 2, the first connection electrode CE1, the second connection electrode CE2 and the third connection electrode CE3 form a connection structure like the Chinese character “ [symbol] ”.

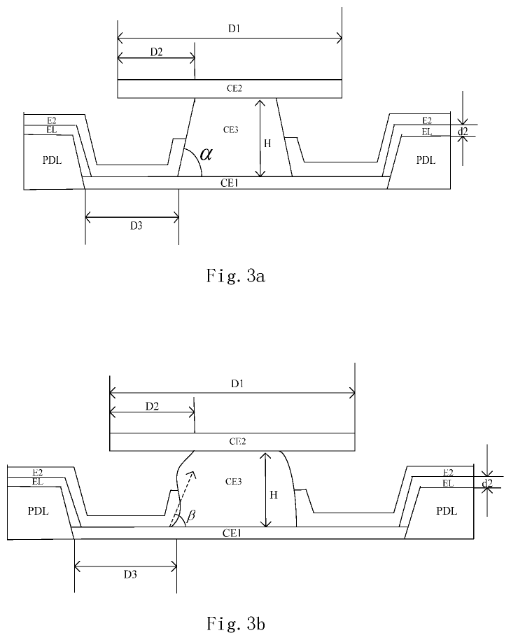

According to some embodiments of the disclosure, the third connection electrode comprises a vertical section perpendicular to the lower surface, the vertical section comprises a top edge in the upper surface, a bottom edge in the lower surface and a side edge connecting the top edge with the bottom edge, the side edge intersects the lower surface at an intersection point in the lower surface, a connection line from any point on the side edge to the intersection point forms an angle with the lower surface, the angle has an opening facing the third connection electrode and is smaller than or equal to 90 degree. With such a slope structure of the third connection electrode formed by this angle, during the process of manufacturing the display panel, the material of the second pixel electrode E2 is easy to spread to a side surface of the third connection electrode CE3, which is beneficial to achieving a greater contact area between the second pixel electrode and the third connection electrode. For example, FIG. 3a illustrates a partial vertical section of the electrode connection structure in a display panel according to another embodiment of the disclosure. As shown in FIG. 3a, the third connection electrode CE3 has a vertical section perpendicular to an upper surface and a lower surface thereof, the vertical section has a height H in a vertical direction. The vertical section of the third connection electrode includes a top edge in the upper surface, a bottom edge in the lower surface and a side edge connecting the top edge with the bottom edge, the side edge and the bottom edge intersect at an acute angle α. The angle α shown in FIG. 3a is just an example of the angle previously mentioned. Additionally, the shape of the side surface of the third connection electrode CE3 is not limited herein. The side surface of the third connection electrode CE3 may be flat, or may have any irregular shapes due to cratering. FIG. 3b illustrates a partial vertical section of an electrode connection structure in a display panel according to yet another embodiment. FIG. 3b shows another example of the above angle β, the third connection electrode includes a non-flat side surface.

By means of a number of experiments, the inventors of the application recognize that the above-mentioned angle has influence on the shape of the third connection electrode. The third connection electrode includes aluminium alloy or other metal material. If the angle is too small, the third connection electrode is prone to bulge during the fabrication process of the display panel, which is disadvantageous to effective contact between the second pixel electrode and the third connection electrode. In some embodiments, the angle has a value greater than or equal to 45 degree and smaller than or equal to 70 degree, thereby preventing the bulge of the third connection electrode while achieving a good contact between the third connection electrode and the second pixel electrode. In the embodiment of FIG. 3a, the vertical section of the third connection electrode CE3 is in a trapezoidal shape. But the shape of the vertical section of the third connection electrode CE3 in the display panel of the embodiment will not be limited to the example shown in FIG. 3a.

According to some embodiments of the disclosure, the display panel further includes a pixel definition layer on the substrate, through which a plurality of sub-pixel regions are formed in the display area. The second pixel electrode extends beyond the pixel definition layer to contact at least one of the first connection electrode and the third connection electrode. The first pixel electrode is separated from the electrode connection structure by the pixel definition layer, which can be further understood from FIG. 2. The pixel definition layer PDL divides the display area of the display panel into a plurality of sub-pixel regions, the second pixel electrode E2 in the sub-pixel region extends beyond the pixel definition layer PDL and contacts the first connection electrode CE1 and the third connection electrode CE3, the first pixel electrode E1 is separated from the electrode connection structure by the pixel definition layer PDL. In this embodiment, with the pixel definition layer PDL, the first pixel electrodes E1 (e.g., the anodes of the OLED) in different sub-pixel regions are independent from each other, and the second pixel electrodes E2 (e.g., the cathodes of the OLED) in different sub-pixel regions are all connected to corresponding auxiliary electrode, thereby respective sub-pixel regions can be controlled independently according to the image to be displayed. In FIG. 2, a thin film transistor for driving the sub-pixels is shown. The thin film transistor in FIG. 2 is of top gate structure, which includes a gate 105, a gate insulating layer 104, a drain 107a, a source 107b and an active layer (including a drain region 103b, a source region 103c and a channel region 103a). FIG. 2 also illustrates a buffer layer 102, a gate wiring 105a, an interlayer insulating layer 106, a passivation layer 108 and a planarization layer 109. The auxiliary electrode 107c is connected to the second pixel electrode E2 via the electrode connection structure (including a first connection electrode CE1, a second connection electrode CE2 and a third connection electrode CE3). The drain 107b of the thin film transistor is connected with the first pixel electrode EC1. In case of an OLED display panel, the sub-pixel region further includes a light emission layer EL between the first pixel electrode E1 and the second pixel electrode E2, as shown in FIG. 2. It can be appreciated that FIG. 2 only shows a partial sectional view of the pixel definition layer PDL, the pixel definition layer PDL may include a plurality of pixel definition strips (a pixel definition strip is a strip structure formed of insulating material). The plurality of pixel definition strips may be arranged along a row direction and a column direction of a sub-pixel region array formed by the plurality of sub-pixel regions of the display area, thereby dividing the display area into a plurality of sub-pixels regions.

In the example of FIG. 2, the orthogonal projection of the first connection electrode CE1 on the substrate 100 covers the orthogonal projection of the second connection electrode CE2 on the substrate 100, the orthogonal projection of the second connection electrode CE2 on the substrate 100 covers the orthogonal projection of the third connection electrode CE3 on the substrate 100, such that the first connection electrode CE1, the second connection electrode CE2 and the third connection electrode CE3 form a cavity having an opening, the opening faces the pixel definition layer PDL. The second pixel electrode E2 extends into the cavity via the opening and contacts the first connection electrode CE1 and the third connection electrode CE3. The structure of the cavity can be well understood by referring to the embodiment of FIG. 3a. As shown in FIG. 3a, the cavity includes an upper wall, a lower wall and a side wall. A portion of the second connection electrode CE2 that extends towards the pixel definition layer PDL and exceeds the third connection layer CE3 acts as the upper wall, a portion of the first connection electrode CE1 that extends towards the pixel definition layer PDL and exceeds the third connection layer CE3 acts as the lower wall, and the side wall is formed by the third connection electrode. A length of the upper wall along a horizontal direction parallel to a surface of the substrate is small than a length of lower wall along the horizontal direction. In FIG. 3a, the length of the upper wall along the horizontal direction parallel to the surface of the substrate is indicated with “D2”, and the length of the lower wall along the horizontal direction parallel to the surface of the substrate is indicated with “D3”. During the process of the manufacturing the display panel, the material of the second pixel electrode E2 is facilitated to extend into the cavity and sufficiently contact the third connection electrode CE3, thereby further reducing the voltage drop on the second pixel electrode when the display panel is in operation. According to some embodiments, the length D3 of the lower wall along the horizontal direction is 4 to 10 times of the length of the upper wall along the horizontal direction. For example, D3 is about 5 micrometers, while D2 is about 0.5 to 1.2 micrometers, by a number of experiment tests, this may ensure that the second pixel electrode E2 extends into the cavity and sufficiently contacts the lower wall and side wall of the cavity during the process of fabricating the second pixel electrode E2, enhancing the contact area between the second pixel electrode E2 and the first connection electrode CE1 and the third connection electrode CE3, further reducing the voltage drop on the extension path of the second pixel electrode when the display panel is in operation. The second connection electrode CE2 has a length D1 along the horizontal direction parallel to the surface of the substrate, which is in a range of 12 micrometers to 14 micrometers.

According to some embodiments, the length D2 of the upper wall along the horizontal direction is 1 to 2 times of a height of the third connection electrode along a second direction which is a vertical direction perpendicular to the horizontal direction. This may prevent too much material of the light emission layer EL from flowing into the cavity during the process of fabricating the display panel. The height of the third connection electrode in the second direction is the height H of the vertical section of the third connection electrode along the vertical direction. According to some embodiments, the height H is 0.5 to 0.6 micrometers, the light emission layer EL has a height d2 about 3200 Å in the second direction. As shown in FIG. 3a, the light emission layer EL in at least some sub-pixel regions may extend beyond the pixel definition layer PDL to reach the auxiliary electrode connection area, the height H of the third connection electrode in the second direction is 1.5 to 2 times of the height D2 of the light emission layer in the second direction.

According to some embodiments, the third connection electrode CE3 in the electrode connection structure and the first pixel electrode E1 in the sub-pixel region are at a same layer and include a same material. For example, in case of a top emission OLED display panel, the first pixel electrode E and the third connection electrode CE3 both include light reflective material, examples of light reflective material include but are not limited to aluminum, molybdenum, silver or an alloy of aluminum, molybdenum or silver. In some embodiments, the first pixel electrode and the third connection electrode both comprise aluminum alloy. The first pixel electrode E1 and the third connection electrode CE3 may be formed simultaneously during a patterning process for a same aluminum alloy film. The phrase “at a same layer” mentioned herein means forming different structures in a same patterning process based on a same film, the different structures are at a same layer.

Referring back to FIG. 2, the sub-pixel region of the display panel further includes a first conductive sub-layer EC1 and a second conductive sub-layer EC2, the second conductive sub-layer EC2 is between the first pixel electrode E1 and the light emission layer EL. The first conductive sub-layer EC1 is on a side of the first pixel electrode E1 facing the substrate 100, the first conductive sub-layer EC1 and the first connection electrode CE1 are at a same layer and include a same material. The second conductive sub-layer EC2 and the second connection electrode CE2 are at a same layer and include a same material, the first conductive sub-layer EC1 and the second conductive sub-layer EC2 are isolated from the electrode connection structure by the pixel definition layer PDL. In some embodiments, each of the first conductive sub-layer EC1, the second conductive sub-layer EC2, the first connection electrode CE1 and the second connection electrode CE2 includes a transparent conductive material, such as indium tin oxide (ITO). The first conductive sub-layer EC1 and the first connection electrode CE1 may be formed during a same pattering process for a same transparent conductive material. Similarly, the second conductive sub-layer EC2 and the second connection electrode CE2 may be formed during a same patterning process for another transparent conductive material.

According to some embodiments, the display panel includes a pixel driving circuit configured to drive the sub-pixel regions to emit light. The transistor shown in FIG. 2 is part of the pixel driving circuit. As shown in FIG. 2, the auxiliary electrode 107c and the source 107b or drain 107a of the transistor are at a same layer and include a same material. For example, the auxiliary electrode 107c, the source 107b and drain 107a of the transistor may be formed during the same patterning process based on a same metal layer, thus the fabrication process for the auxiliary electrode may be simplified and the cost for manufacturing the display panel is saved. In addition, like the drain 107a and source 107b of the transistor, the auxiliary electrode 107c is below the light emission layer of the sub-pixel region, thereby avoiding the influence to the performance of the light emission layer of the sub-pixel region by the auxiliary electrode.

According to some embodiments, the second pixel electrodes in respective sub-pixel regions of the display panel are connected to each other to form an integral structure. Therefore, the second pixel electrodes E2 in the sub-pixel regions and the auxiliary electrodes 07c in the auxiliary electrode connection regions would have a same voltage when the display panel is in operation. For example, the second pixel electrodes in the sub-pixel regions of the display panel may form an integral plate-like cathode (serving as the cathode of respective OLED sub-pixels), the auxiliary electrodes are connected to the plate-like cathode via a corresponding electrode connection structure. In this way, voltage drop on the cathode of OLED sub-pixels of the display panel may be further reduced when the display panel is in operation, thereby achieving thinness of the cathode and enhancing light transmittance of the display device.

In the embodiment of FIG. 2, the display panel further includes a light shielding layer 101 between the substrate 100 and the pixel driving circuit, an orthogonal projection of the light shielding layer 101 on the substrate covers an orthogonal projection of an active layer (including an source region 103c, a drain region 104b and a channel region 103a) of the transistor on the substrate. The light shielding layer 101 may reduce the amount of ambient light irradiating onto the active layer through the substrate 100, which is advantageous to stability of operation performance of the transistor. The transistor shown in FIG. 2 is of top gate type, this will not limit the possible embodiments of the disclosure. The pixel driving circuit may include a bottom gate transistor in other embodiments.

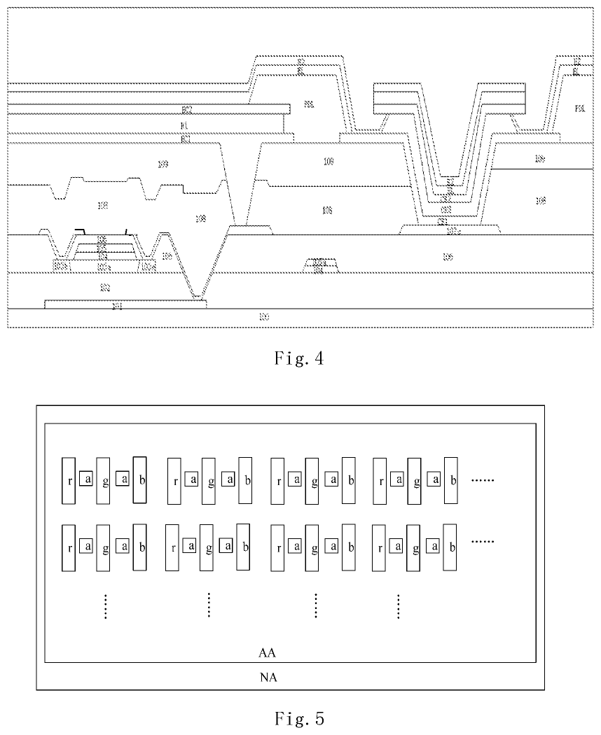

FIG. 4 illustrates a partial vertical section of a display panel according to another embodiment of the disclosure. The display panel shown in FIG. 4 is basically the same to the display panel in FIG. 2, the differences lie in that the main portions of the first connection electrode CE1, the second connection electrode CE2 and the third connection electrode CE3 of the electrode connection structure are all located in a via hole of the insulating layer (e.g., including the passivation layer 108 and the planarization layer 109). Therefore, the display panel illustrated in FIG. 4 has the same advantages or technical effect with the embodiment shown in FIG. 2, which will not be repeated herein. In addition, the display panel further comprise other essential structures above the second pixel electrode E2 and covering the second pixel electrode E2, which is not the key of the disclosure and will not be described in detail.

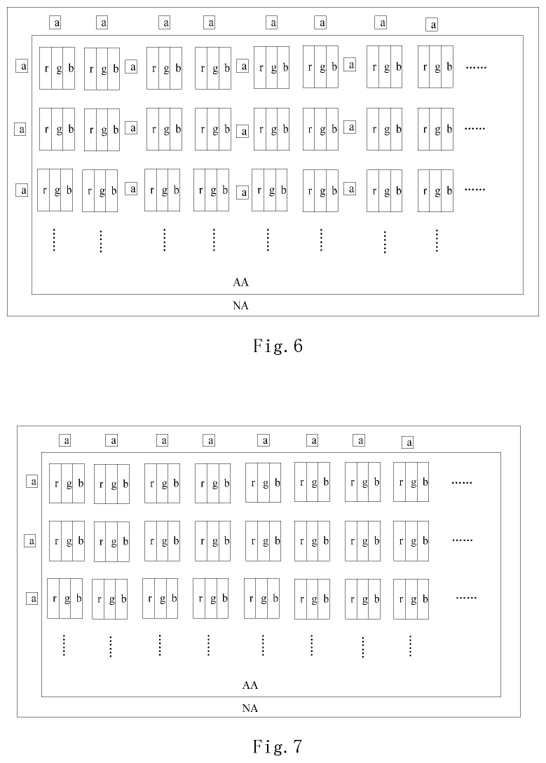

In the embodiment of FIG. 1, the display area of the display panel includes a plurality of pixel units, each pixel unit includes at least three sub-pixel regions of the plurality of sub-pixel regions, e.g., a red sub-pixel region r, a green sub-pixel region g and a blue sub-pixel region b. At least some auxiliary electrode connection regions of the display panel are located between adjacent pixel units of the plurality of pixel units. Alternatively, in other embodiments, the display panel includes a plurality of auxiliary electrode connection regions, at least some of the plurality of auxiliary electrode connection regions are located between adjacent sub-pixel regions of the plurality of sub-pixel regions. As shown in FIG. 5, the auxiliary electrode connection regions α are distributed among adjacent sub-pixel regions r, g and b. Or, in other embodiments, at least some auxiliary electrode connection regions of the display panel are in the non-display area the display panel. As shown in FIG. 6, at least some auxiliary electrode connection regions α are in a non-display area NA of the display panel, thereby decreasing the number of the auxiliary electrode connection regions α in the display area AA or reducing the auxiliary electrode connection regions in the display area AA, which is advantageous to enhance the aperture ratio in the display area AA. Or, as shown in FIG. 7, all auxiliary electrode connection regions α are in the non-display area NA of the display panel, thereby preventing the auxiliary electrode connection regions from affecting the aperture ration of the display area AA, while reducing the voltage drop on the second pixel electrode extension path when the display panel is in operation. The auxiliary electrodes are not shown in FIGS. 5 to 7 for simplicity.

Another embodiment of the disclosure provides a display device including the display panel as described in any of the foregoing embodiments. The display device may be any electronic device having display function or components in the electronic device. Examples of the display device include but are not limited to vehicle-mounted display, show window display, television or watch, etc.

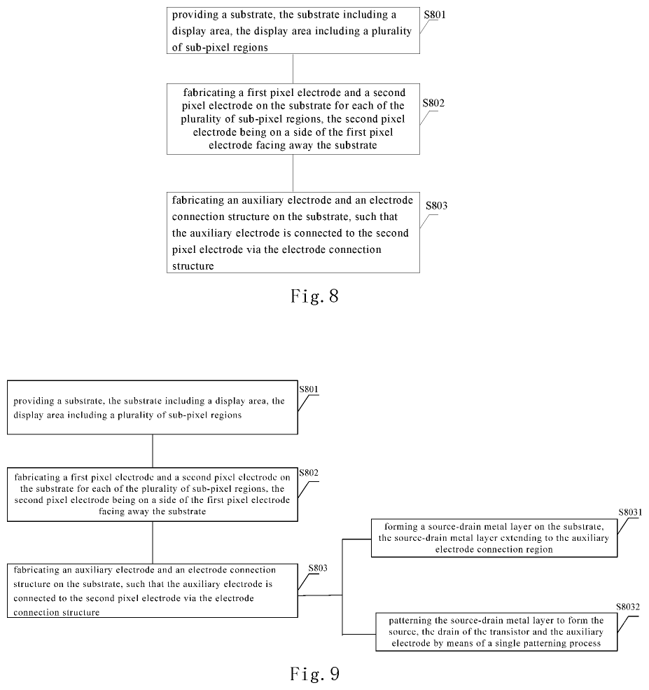

Another embodiment of the disclosure provides a method for manufacturing a display panel. As shown in FIG. 8, the method comprises the following steps. S801, providing a substrate, the substrate including a display area, the display area including a plurality of sub-pixel regions; S802, fabricating a first pixel electrode and a second pixel electrode on the substrate for each of the plurality of sub-pixel regions, the second pixel electrode being on a side of the first pixel electrode facing away the substrate; S803, fabricating an auxiliary electrode and an electrode connection structure on the substrate, such that the auxiliary electrode is connected to the second pixel electrode via the electrode connection structure, the electrode connection structure being in the auxiliary electrode connection region, an orthogonal projection of the auxiliary electrode connection region on the substrate having no overlap with orthogonal projections of the sub-pixel regions on the substrate. The electrode connection structure includes a first connection electrode on the auxiliary electrode, a second connection electrode on a side of the first connection electrode facing away the substrate and a third connection electrode between the first connection electrode and the second connection electrode. The third connection electrode includes an upper surface contacting the second connection electrode, a lower surface contacting the first connection electrode and opposite to the upper surface, and a vertical section perpendicular to the upper surface or the lower surface. The vertical section includes a top edge in the upper surface and a bottom edge in the lower surface, an orthogonal projection of the bottom edge on the substrate covers an orthogonal projection of the top edge on the substrate.

Utilizing the method for manufacturing the display panel according to the above embodiment to manufacture a display panel, a technical effect similar to the embodiment of the display panel can be achieved, i.e., a thinner second pixel electrode is allowed, which may enhance the light transmittance of the display panel, while the voltage drop on the second pixel electrode can be reduced, brightness uniformity of the image displayed by the display panel can be improved.

According to some embodiments of the disclosure, the method for manufacturing a display panel further comprises fabricating a pixel driving circuit on the substrate, the pixel driving circuit including a transistor. In this embodiment, the drain and the source of the transistor and the auxiliary electrode may be formed in a same patterning process. As shown in FIG. 9, the step S803 comprises: S8031, forming a source-drain metal layer on the substrate, the source-drain metal layer extending to the auxiliary electrode connection region; S8032, patterning the source-drain metal layer to form the source, the drain of the transistor and the auxiliary electrode by means of a single patterning process. The phrase “single patterning process” mentioned herein means utilizing a single mask in a patterning process to form desired structures(e.g., the source, drain and the auxiliary electrode). Therefore these structures are formed in a same patterning process, simplifying the fabrication process of the display panel and reducing the cost of manufacturing the display panel.

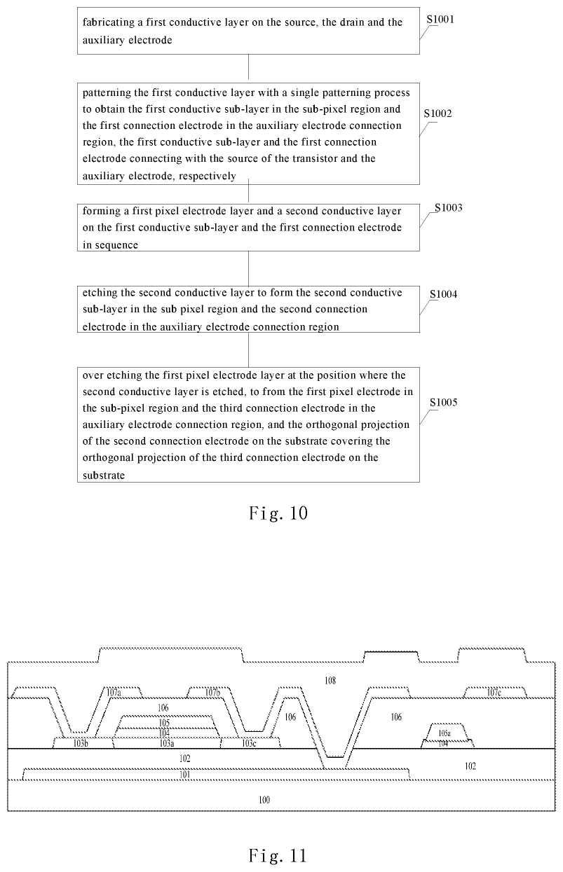

According to some embodiments of the disclosure, the sub-pixel region of the display panel further comprises a first conductive sub-layer and a second conductive sub-layer, the second conductive sub-layer is between the first pixel electrode and the second pixel electrode, the first conductive sub-layer is on a side of the first pixel electrode facing the substrate. In this case, the first conductive sub-layer, the first pixel electrode and the second conductive sub-layer may be fabricated in a same process as the first connection electrode, the third connection electrode and the second connection electrode, respectively. In other words, as shown in FIG. 10, fabricating the electrode connection structure, the first conductive sub-layer, the second conductive sub-layer and the first pixel electrode may include the following steps: S1001, fabricating a first conductive layer on the source, the drain and the auxiliary electrode; S1002, patterning the first conductive layer with a single patterning process to obtain the first conductive sub-layer in the sub-pixel region and the first connection electrode in the auxiliary electrode connection region, the first conductive sub-layer and the first connection electrode connecting with the source of the transistor and the auxiliary electrode, respectively; S1003, forming a first pixel electrode layer and a second conductive layer on the first conductive sub-layer and the first connection electrode in sequence; S1004, etching the second conductive layer to form the second conductive sub-layer in the sub pixel region and the second connection electrode in the auxiliary electrode connection region; and S1005, over etching the first pixel electrode layer at the position where the second conductive layer is etched, to from the first pixel electrode in the sub-pixel region and the third connection electrode in the auxiliary electrode connection region, and the orthogonal projection of the second connection electrode on the substrate covering the orthogonal projection of the third connection electrode on the substrate. The wording “over etching” mentioned herein refers to the first pixel electrode layer is etched more significantly than the second conductive layer, such that the first pixel electrode layer has a greater indentation at the position of etching to form the second connection electrode, in other words, the second connection electrode extends outwards a certain distance relative to the third connection electrode.

According to some embodiments, the method for manufacturing the display panel further comprises: forming a pixel definition layer on the substrate, the display area being divided into a plurality of sub-pixel regions through the pixel definition layer, the first conductive sub-layer, the first pixel electrode and the second conductive sub-layer in the sub-pixel region are isolated from the electrode connection structure in the auxiliary electrode connection region by the pixel definition layer; and fabricating a light emission layer on the second conductive sub-layer. Accordingly, fabricating the second pixel electrode include: forming the second pixel electrode on the light emission layer and the pixel definition layer, the second pixel electrode extending beyond the pixel definition layer to contact at least one of the first connection electrode and the third connection electrode.

Next, some steps of the method for manufacturing the display panel according to the embodiment of the disclosure will be described in detail by referring to the example shown in FIGS. 11 to 16.

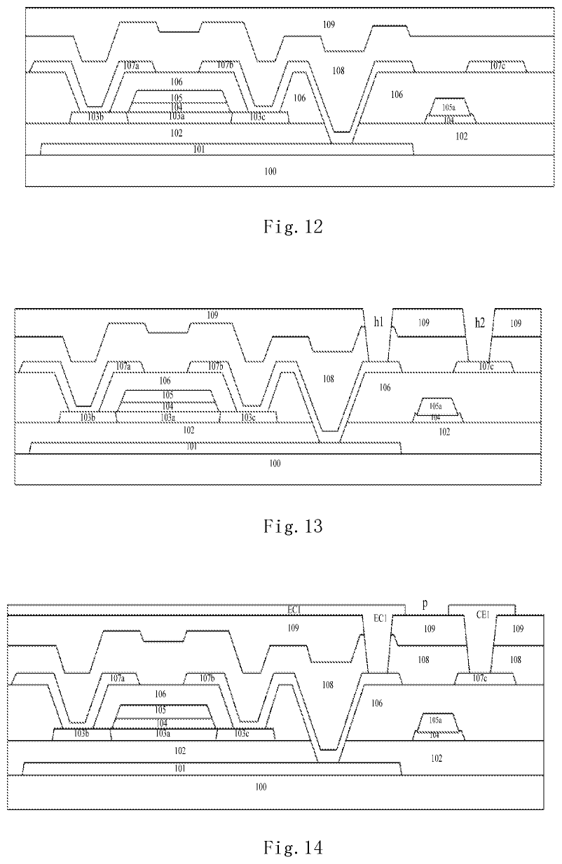

Referring to FIG. 11, an auxiliary electrode 107c and a pixel circuit for driving the sub-pixels are fabricated on the substrate 100. The transistor in the pixel circuit may include a gate 105, a gate insulating layer 104, a drain 107a, a source 107b and an active layer (including a drain region 103b, a source region 103 and a channel region 103a). In addition, other essential structures such as a light shielding layer 101, a buffer layer 102, a gate wiring 105a, a interlayer insulating layer 106 and a passivation layer 108 may be fabricated on the substrate 100. The auxiliary electrode 107c and the source 107b, drain 107a of the transistor may be formed during a single patterning process to simplify the process of fabricating auxiliary electrode. For example, after a patterned interlayer insulating layer 106 is formed, a source-drain metal layer is fabricated on the patterned interlayer insulating layer 106, and patterning the source-drain metal layer to form the auxiliary electrode 107c and the source 107b and drain 107a of the transistor. As shown in FIG. 12, a planarization layer 109 is formed on the passivation layer 108 after the passivation layer is fabricated, the material of the planarization layer 109 includes but is not limited to resin.

In the following, as shown in FIG. 13, forming a first via hole h1 and a second via hole h2 at a position corresponding to the source 107b of the transistor and a position corresponding to the auxiliary electrode 107c, respectively, the first via hole h1 and the second via hole h2 both penetrating the passivation layer 108 and the planarization layer 109, thereby obtaining a patterned planarization layer 109 and a patterned passivation layer 108. As shown in FIG. 14, a material (e.g., indium tin oxide) of the first conductive layer is deposited on the patterned planarization layer 109, the material of the first conductive layer fills the first via hole h1 and the second via hole h2 to form the first conductive layer, the first conductive layer is connected with the source 107b and the auxiliary electrode 107c respectively via the first via hole h1 and the second via hole h2. Afterwards, the first conductive layer is patterned, forming the first conductive sub-layer EC1 in the sub-pixel region and the first connection electrode CE1 in the auxiliary electrode connection region, the patterned first conductive layer includes an opening p such that the first conductive sub-layer EC1 and the first connection electrode CE1 are independent and insulated from each other.

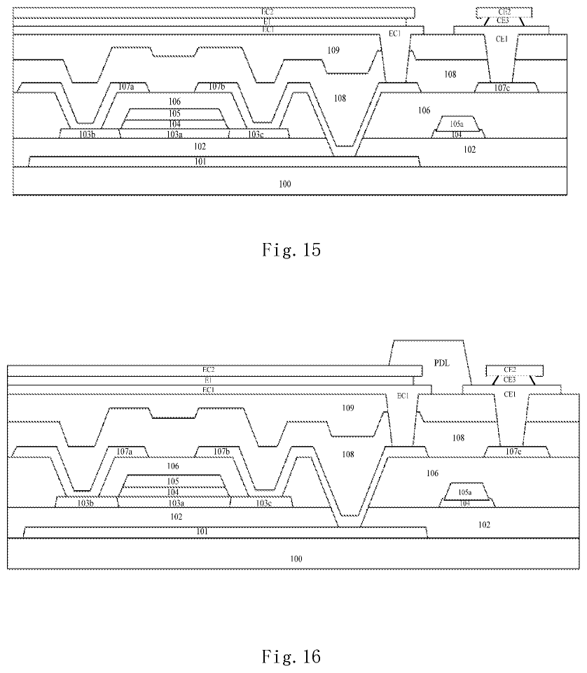

In the following, forming a first pixel electrode layer and a second conductive layer on the first conductive layer in sequence. The first pixel electrode layer may include reflective metal material (including but is not limited to aluminum alloy), the second conductive layer includes indium tin oxide, etc. Then performing etching on the second conductive layer and the first pixel electrode layer successively at the opening p in the patterned first conductive layer. For example, dilute acid such as H₂SO₄ may be used to etch the second conductive layer, then concentrated acid such as H₃PO₄ may be used to over etch the first pixel electrode layer, to pattern the second conducive layer and the first pixel electrode layer respectively, openings in the patterned second conductive layer and first pixel electrode layer expose the opening p in the patterned first conductive layer, the second conductive sub-layer EC2, the second connection electrode CE2, the first pixel electrode E1 and the third connection electrode CE3 are formed, as shown in FIG. 15. By over etching the first pixel electrode layer, such that the opening formed in the first pixel electrode layer is larger than the opening formed in the second conductive layer, and the third connection electrode CE3 has a slope structure, the second connection electrode CE2 extends outwards a certain distance relative to the third connection electrode CE3. In other words, the orthogonal projection of the second connection electrode CE2 on the substrate covers the orthogonal projection of the third connection electrode CE3 on the substrate. In some embodiments, with the above-mentioned over etching, the obtained third connection electrode CE3 has a trapezoid vertical section, a base angle of the trapezoid vertical section is greater than or equal to 45 degree and smaller than or equal to 70 degree. For example, in some embodiments, in the patterning process of the first pixel electrode layer, the time during which the etchant (e.g., concentrated acid such as H₃PO₄) reacts with the first pixel electrode layer can be controlled to obtain a third connection electrode CE3 having a trapezoidal vertical section. In an experimental example where a first pixel electrode layer having a thickness of 0.6 micrometers and including aluminium alloy is etched, the first pixel electrode layer begins to generate a via hole 110 seconds after the concentrated acid H₃PO₄ is applied to the first pixel electrode, and a third connection electrode CE3 having a trapezoidal vertical section is formed 143 to 176 seconds after the concentrated acid H₃PO₄ is applied to the first pixel electrode. Therefore, by controlling the time during which the etchant reacts with the first pixel electrode layer, a desired third connection electrode can be fabricated. The first connection electrode CE1, the second connection electrode CE2 and the third connection electrode CE3 form an electrode connection structure like a Chinese character “ [symbol] ”. This electrode connection structure includes a cavity having an opening formed by the first connection electrode, the second connection electrode and the third connection electrode. The electrode connection structure is disconnected from the first conductive sub-layer EC1, the first pixel electrode E1 and the second conductive sub-layer EC2 by the opening formed in the etching process previously described.

As shown in FIG. 16, a pixel definition layer PDL is formed at an opening between the electrode connection structure and the first conductive sub-layer EC1, the first pixel electrode E1 and the second conducive sub-layer EC2, the pixel definition layer PDL fills a part of the opening between the electrode connection structure and the first conductive sub-layer EC1, the first pixel electrode E1 and the second conducive sub-layer EC2, but does not extend into the interior of the cavity formed by the first connection electrode, the second connection electrode and the third connection electrode. Thereafter, a light emission layer is formed on the conductive sub-layer EC2. In some embodiments, referring back to FIG. 2, an organic electroluminescent layer is formed by an evaporation process, the electroluminescent layer EL extends beyond the pixel definition layer PDL. Forming the electroluminescent layer EL by the evaporation process, the material of the electroluminescent layer EL is able to have a poor diffusion during the process of forming the electroluminescent layer EL, thus the portion (i.e., the upper wall of the cavity of the electrode connection structure described in the previous embodiment of the display panel) of the second connection electrode CE2 of the electrode connection structure that extends towards the pixel definition layer PDL and exceeds the third connection electrode CE3 may block the material of the electroluminescent layer from entering the interior of the cavity, the material of the electroluminescent layer would not form a continuous structure with the electroluminescent layer on the pixel definition layer, even if some of the electroluminescent layer material is deposited above the second connection electrode CE2 in the evaporation process. This provides a good basis for a good connection between a second pixel electrode to be formed and the electrode connection structure. Continuing refer to FIG. 2, in some embodiments, a second pixel electrode E2 is formed on the electroluminescent layer EL by a sputtering process. For example, a material of indium-zinc-oxide (IZO) is sputtered on the light emission layer EL, the IZO layer sputtered is able to have a good diffusion, the material of IZO may be deposited onto the first connection electrode CE1 and bypass the upper wall of the cavity of the electrode connection structure. Since the third connection electrode CE3 has a slope structure (e.g., the third connection electrode CE3 has a trapezoidal vertical section with an acute base angle), the material of the second pixel electrode may easily climb along the third connection electrode CE3 during the sputtering process for forming the second pixel electrode E2, such that the second pixel electrode E2 has a larger contact area with the third connection electrode CE3 and the first connection electrode CE1, the voltage drop on the second pixel electrode can be further decreased when the display panel is in operation.

The technical solution of the disclosure has been described with reference to some embodiments, but possible embodiments of the solution are not limited to those specifically described herein. On the contrary, the scope of the application is defined by the appended claims. It is to be understood that, the terms like first, second used herein are used to describe various devices, elements, components or parts, but these devices, elements, components and parts should not be limited by the terms. They are only used to distinguish one device, element, component or part from another device, element, component or part. The term “connect” and its conjugations include direct connection and indirect connection.

Additionally, although a single feature may be included in different claims, this does not mean that combination of different features of different claims is impracticable and/or disadvantageous, instead, different features in different claims can be combined. The order of the features in the claims does not indicate an operation order for the features. Further, in the claims set, the wording “comprise” and its conjugations do not exclude 10 presence of other elements, and the article “a” or “an” does not exclude plurals.

1. A display panel comprising a substrate, wherein a display area of the display panel comprises a plurality of sub-pixel regions, each sub-pixel of the plurality of sub-pixel regions comprises a first pixel electrode on the substrate and a second pixel electrode on a side of the first pixel electrode facing away the substrate,
wherein the display panel further comprises an auxiliary electrode connection region, the auxiliary electrode connection region comprises an auxiliary electrode and an electrode connection structure on the substrate, the second pixel electrode is connected to the auxiliary electrode via the electrode connection structure, and an orthogonal projection of the auxiliary electrode connection region on the substrate has no overlap with orthogonal projections of the plurality of sub-pixel regions on the substrate,
wherein the electrode connection structure comprises a first connection electrode on the auxiliary electrode, a second connection electrode on a side of the first connection electrode facing away the substrate, and a third connection electrode between the first connection electrode and the second connection electrode,
wherein the third connection electrode comprises an upper surface contacting the second connection electrode, a lower surface contacting the first connection electrode and opposite to the upper surface, and a vertical section perpendicular to the upper surface or the lower surface, the vertical section comprises a top edge in the upper surface and a bottom edge in the lower surface, wherein an orthogonal projection of the bottom edge on the substrate covers an orthogonal projection of the top edge on the substrate.

2. The display panel according to claim 1, wherein an orthogonal projection of the first connection electrode on the substrate covers an orthogonal projection of the second connection electrode on the substrate, an orthogonal projection of the third connection electrode on the substrate does not exceed the orthogonal projection of the second connection electrode on the substrate.

3. The display panel according to claim 2, wherein the vertical section comprises a side edge connecting the top edge to the bottom edge, the side edge intersects the lower surface at an intersecting point in the lower surface, wherein a connection line from any point on the side edge to the intersecting point forms an angle with the lower surface, an opening of the angle faces the third connection electrode and is smaller than or equal to 90 degree.

4. The display panel according to claim 3, the angle is greater than or equal to 45 degree and smaller than or equal to 70 degree.

5. The display panel according to claim 1, wherein the display panel further comprises a pixel definition layer on the substrate, the display area is divided into the plurality of sub-pixel regions by the pixel definition layer, the second pixel electrode extends beyond the pixel definition layer to contact at least one of the first connection electrode and the third connection electrode, the first pixel electrode and the electrode connection structure are isolated from each other by the pixel definition layer.

6. The display panel according to claim 5, wherein an orthogonal projection of the second connection electrode on the substrate covers an orthogonal projection of the third connection electrode on the substrate, such that the first connection electrode, the second connection electrode and the third connection electrode form a cavity having an opening, wherein the opening faces the pixel definition layer, the second pixel electrode extends into the cavity through the opening and contacts the first connection electrode and the third connection electrode.

7. The display panel according to claim 6, wherein the cavity comprises an upper wall, a lower wall and a side wall, wherein a portion of the second connection electrode extending towards the pixel definition layer and exceeding the third connection layer serves as the upper wall, a portion of the first connection electrode extending towards the pixel definition layer and exceeding the third connection layer serves as the lower surface, the third connection electrode forms the side wall, and wherein a length of the upper wall along a horizontal direction parallel to a surface of the substrate is smaller than a length of the lower surface along the horizontal direction.

8. The display panel according to claim 7, wherein the length of the lower wall along the horizontal direction is 4 to 10 times of the length of the upper wall along the horizontal direction.

9. The display panel according to claim 7, wherein a height of the third connection electrode in a second direction is 1.5 to 6 times of a height of the second pixel electrode in the second direction, the second direction is a vertical direction perpendicular to the horizontal direction.

10. The display panel according to claim 1, the third connection electrode and the first pixel electrode are at a same layer and comprise a same material.

11. The display panel according to claim 10, wherein each of the third connection electrode and the first pixel electrode comprises a light reflective material.

12. The display panel according to claim 11, wherein the light reflective material comprises aluminum alloy.

13. The display panel according to claim 5, wherein the sub-pixel region further comprises a first conductive sub-layer and a second conductive sub-layer, the second conductive sub-layer is between the first pixel electrode and the second pixel electrode, the first conductive sub-layer is on a side of the first pixel electrode facing the substrate, wherein the first conductive sub-layer and the first connection electrode are at a same layer and comprise a same material, the second conductive sub-layer and the second connection electrode are at a same layer and comprise a same material, wherein the first conductive sub-layer and the second conductive sub-layer are isolated from the electrode connection structure by the pixel definition layer.

14. The display panel according to claim 1, wherein the display panel further comprises a pixel driving circuit configured to drive the plurality of sub-pixel regions to emit light, the pixel driving circuit comprises a transistor, wherein the auxiliary electrode and a drain or a source of the transistor are at a same layer and comprise a same material.

15. The display panel according to claim 1, wherein respective second pixel electrodes in the plurality of sub-pixel regions are connected with each other to form an integral structure.

16. The display panel according to claim 14, wherein the display panel further a light shielding layer between the substrate and the pixel driving circuit, an orthogonal projection of the light shielding layer on the substrate covers an orthogonal projection of an active layer of the transistor on the substrate.

17. The display panel according to claim 1, wherein the display panel comprises a plurality of auxiliary electrode connection regions including the auxiliary electrode region, at least some of the plurality of auxiliary electrode regions are located between adjacent sub-pixel regions of the plurality of sub-pixel regions.

18. The display panel according to claim 1, wherein the display area comprises a plurality of display units, each display unit comprises at least three sub-pixel regions of the plurality of the sub-pixel regions,
wherein the display panel comprises a plurality of auxiliary electrode connection regions comprising the auxiliary electrode connection region, wherein at least some of the plurality of auxiliary electrode connection regions are located between adjacent pixel units of the plurality of pixel units.

19. The display panel according to claim 1, wherein the display panel comprises a non-display area outside the display area, wherein the display panel comprises a plurality of auxiliary electrode connection regions including the auxiliary electrode connection region, wherein at least some of the plurality of auxiliary electrode connection regions are in the non-display area.

20. A display device, comprising the display panel according to claim 1.

21.-24. (canceled)
